(19) United States
(12) Patent Application Publication
(10) Pub. No.: US 2022/0140633 A1
(43) Pub. Date: May 5, 2022

(54) Power Tool

(71) Applicant: Techway Industrial Co., Ltd., Taichung (TW)

(72) Inventors: Fu Hsiang Chung, Taichung (TW); Chen Chen Cheng, Taichung (TW); Kuo Chou Li, Taichung (TW)

(21) Appl. No.: 17/508,233

(22) Filed: Oct. 22, 2021

(30) Foreign Application Priority Data
Nov. 4, 2020 (TW) 109138461

(51) Int. Cl. H02J 7/00; H05K 7/14

(52) U.S. Cl. CPC H02J 7/0063; H05K 7/1427; H02J 7/0042

(57) ABSTRACT

A power tool has a housing and a control assembly. The control assembly is disposed within the housing and has a switch, and a controlling circuit board. The switch has a length and a width. The length is defined along the housing. The width is defined along a radial direction of the housing and is smaller than the length of the switch to form two convection passages between the switch and the housing. The two convection passages are formed between the switch and the housing to facilitate ventilation inside the power tool and promote heat-dissipation efficiency of the power tool.

### BACKGROUND OF THE INVENTION

### 1. Field of the Invention

The present invention relates to a power tool, and more particularly to a power tool with convection passages for heat dissipation.

### 2. Description of Related Art

With reference to FIGS. 8 and 9, a power tool is a common hand tool. A conventional power tool usually has an output shaft, a housing 71, and a battery, a motor 73 and a control assembly 75 mounted within the housing 71. The output shaft and the battery are respectively disposed at a front end and a rear end of the conventional power tool. The motor 73 is disposed adjacent to the front end of the conventional power tool and is disposed behind the output shaft. The motor 73 is connected to the output shaft for providing power to the output shaft. A ventilation hole 731 is disposed at a rear end of the motor 73. The control assembly 75 is configured to control operation of the conventional power tool and is disposed between the motor 73 and the battery. The control assembly 75 has a switch 751 and two controlling circuit boards 753. One of the controlling circuit boards 753 is disposed between the switch 751 and the battery. The other one of the controlling circuit boards 753 is disposed between the motor 73 and the switch 751 and is connected to a heat-dissipation board 755.

When in use, the conventional power tool generates heat due to operation of the motor 73. Parts inside the conventional power tool are easily damaged due to the heat accumulated and undissipated inside the conventional power tool. Therefore, the motor 73 of the conventional power tool has a radiator fan for dissipating the heat. The radiator fan introduces air into the motor 73 via the ventilation hole 731 disposed at the rear end of the motor 73, and then dissipates the heat to an outside of the conventional power tool via convection holes of the housing 71.

However, one of the heat-dissipation boards 755 that is disposed between the motor 73 and the switch 751 blocks airflow passing through the ventilation hole 731 disposed at the rear end of the motor 73 and diminishes heat-dissipation of the conventional power tool. Moreover, a lengthwise edge of the switch 751 of the control assembly 75 is perpendicular to a lengthwise direction of the conventional power tool, such that widthwise edges of the switch 751 are close to the housing 71, a space between the switch 751 and the housing 71 is narrow, circulation of the airflow is obstruct, and also generate negative effect to the heat-dissipation of the conventional power tool. Furthermore, the two controlling circuit boards 753 have to be electrically connected to the switch 751 via cables and arranged at both sides of the switch 751. The two controlling circuit boards 753 arranged at the both sides of the switch 751 prolong the control assembly 75 and increase a total length of the conventional power tool. Therefore, structural design of the conventional power tool has to be further improved to promote the heat-dissipation efficiency and shorten the length of the conventional power tool.

To overcome the shortcomings of the conventional power tool, the present invention provides a power tool to mitigate or obviate the aforementioned problems.

### SUMMARY OF THE INVENTION

The main objective of the present invention is to provide a power tool that has efficient heat dissipation and is short in length.

The power tool has a housing and a control assembly. The control assembly is disposed within the housing and has a switch, and a controlling circuit board. The switch has a length and a width. The length is defined along the housing. The width is defined along a radial direction of the housing and is smaller than the length of the switch to form two convection passages between the switch and the housing. The two convection passages are formed between the switch and the housing to facilitate ventilation inside the power tool and promote heat-dissipation efficiency of the power tool.

Other objects, advantages, and novel features of the invention will become more apparent from the following detailed description when taken in conjunction with the accompanying drawings.

### BRIEF DESCRIPTION OF THE DRAWINGS

FIG. 1 is a perspective view of a power tool in accordance with the present invention;

FIG. 2 is an exploded perspective view of the power tool in FIG. 1;

FIG. 3 is a perspective view of the power tool in FIG. 1, showing a housing and a pressing operator omitted;

FIG. 4 is an exploded perspective view of a control assembly of the power tool in FIG. 2;

FIG. 5 is another exploded perspective view of the control assembly of the power tool in FIG. 2;

FIG. 6 is an enlarged side view of the power tool in FIG. 3;

FIG. 7 is a cross-sectional front view of the power tool in FIG. 1;

FIG. 8 is a partial perspective view of a conventional power tool in accordance with the prior art; and

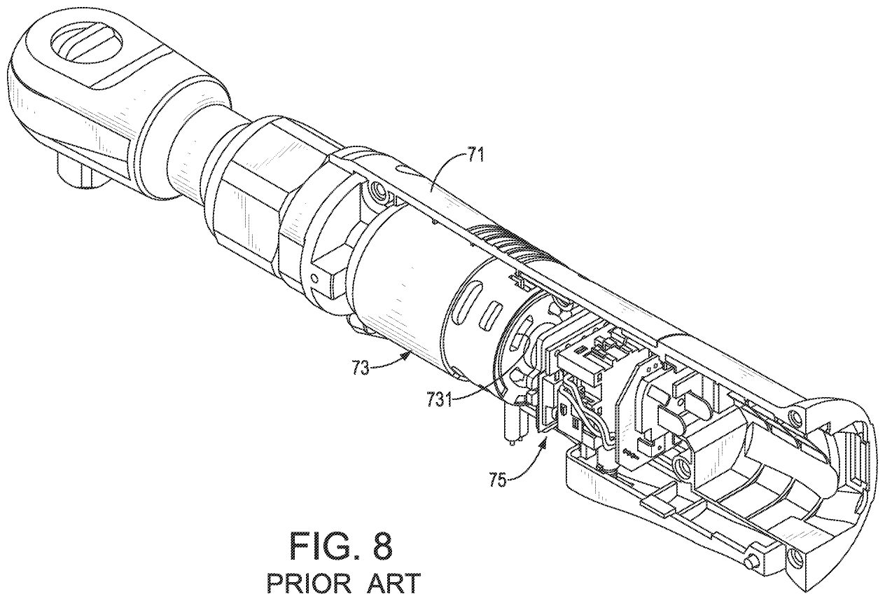

FIG. 9 is an exploded perspective view of a control assembly of the conventional power tool in FIG. 8.

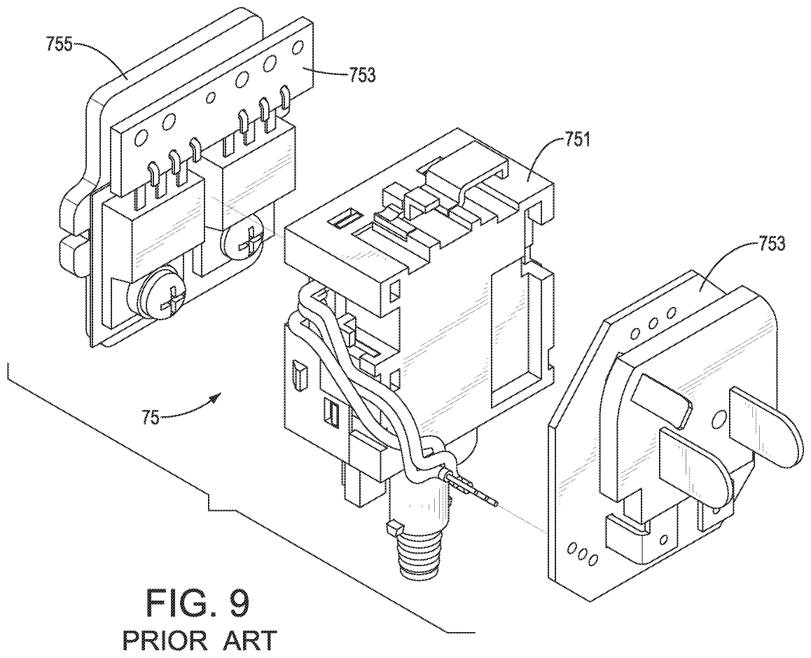

### DETAILED DESCRIPTION OF PREFERRED EMBODIMENTS

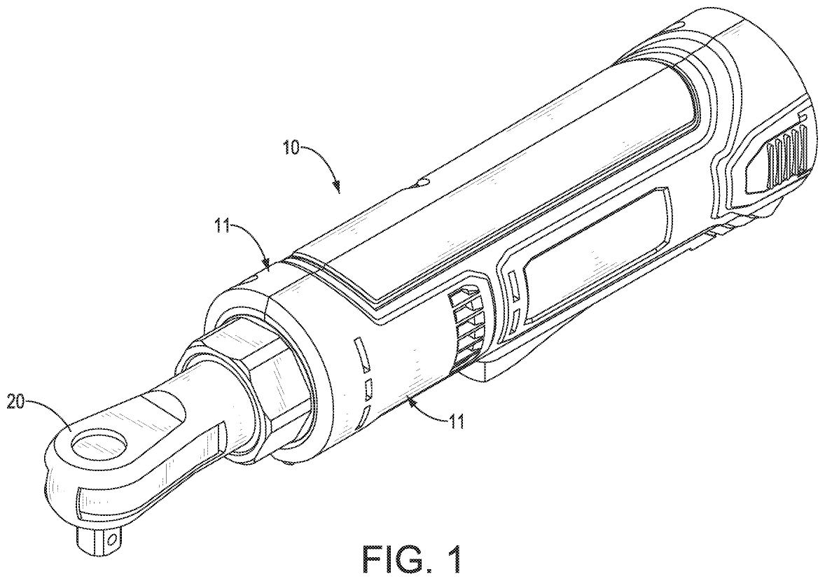

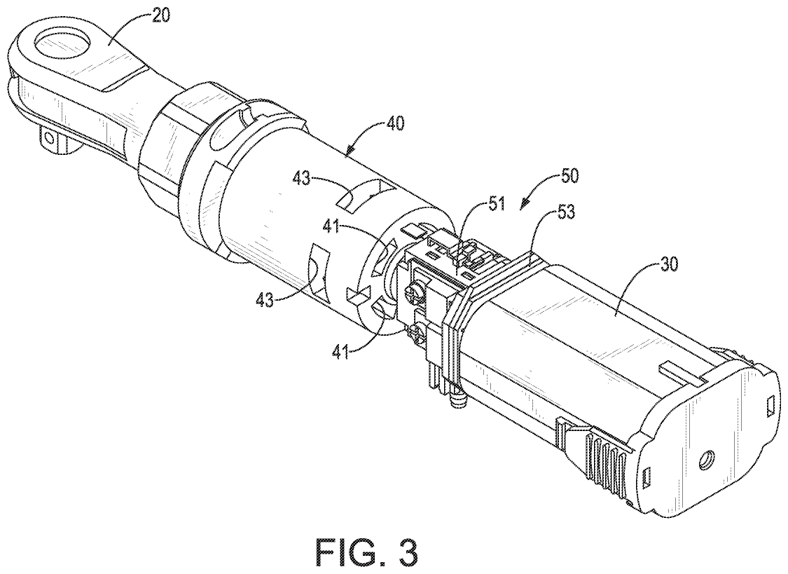

With reference to FIGS. 1 to 3, a power tool in accordance with the present invention has a housing 10, an output head 20, a battery 30, a motor 40, and a control assembly 50.

With reference to FIGS. 1 to 3, the housing 10 has a receiving space, a first end, a second end, and two shells 11. The receiving space is formed within the housing 10. The first end and the second end of the housing 10 are disposed oppositely on the housing 10. In the present invention, the housing 10 is assembled by the two shells 11 connected mutually. There are multiple convection holes 111 radially formed through each shell 11.

With reference to FIGS. 1 to 3, the output head 20 is disposed at the first end of the housing 10. The output head 20 is configured to connect accessories such as sleeves.

With reference to FIGS. 1 to 3, the battery is disposed in the receiving space of the housing 10 and is disposed adjacent to the second end of the housing 10. The battery 30 provides electric power to the motor 40.

With reference to FIGS. 1 to 3, the motor 40 provides the output head 20 with power. The motor 40 is disposed in the receiving space of the housing 10, is disposed adjacent to the first end of the housing 10, and is connected to the output head 20. The motor 40 has at least one ventilation hole 41 and at least one heat-dissipation hole 43. The at least one ventilation hole 41 faces to the second end of housing 10. The at least one heat-dissipation hole 43 faces to the housing 10. The motor 40 further has a centrifugal fan disposed therein to introduce exterior air into the motor 40 via the at least one ventilation hole 41. Heat generated by operation of the motor 40 is dissipated from the at least one heat-dissipation hole 43 and then dissipated via the multiple convection holes 111.

With reference to FIGS. 1 to 3, the control assembly 50 is disposed in the receiving space of the housing 10 and is disposed between the battery 30 and the motor 40. The control assembly 50 is electrically connected to the battery 30 and the motor 40. The control assembly 50 has a switch 51, a button 52, a controlling circuit board 53, a heat-dissipation board 54, a freewheeling diode 55, a capacitor 56, a pressing operator 57, and a field-effect transistor 58.

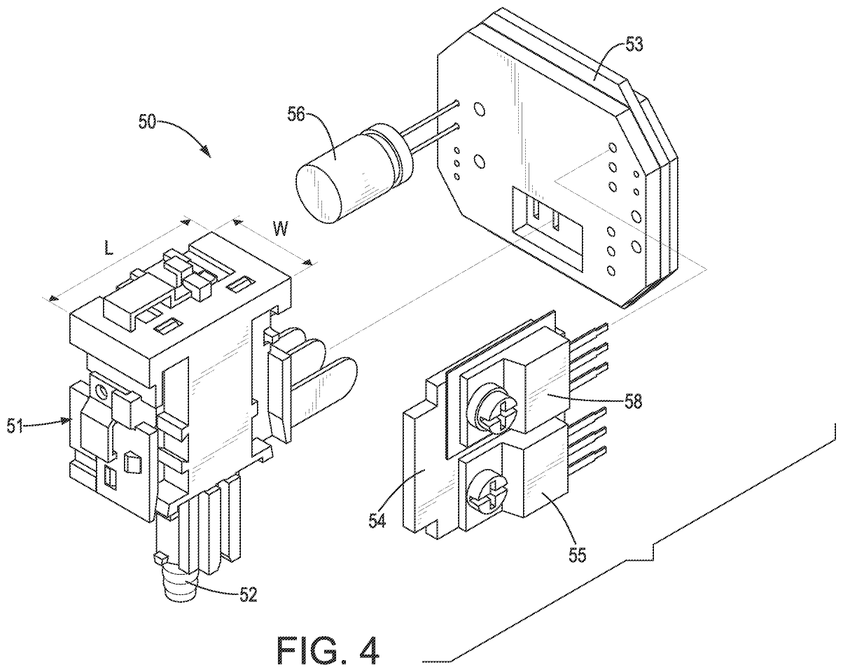

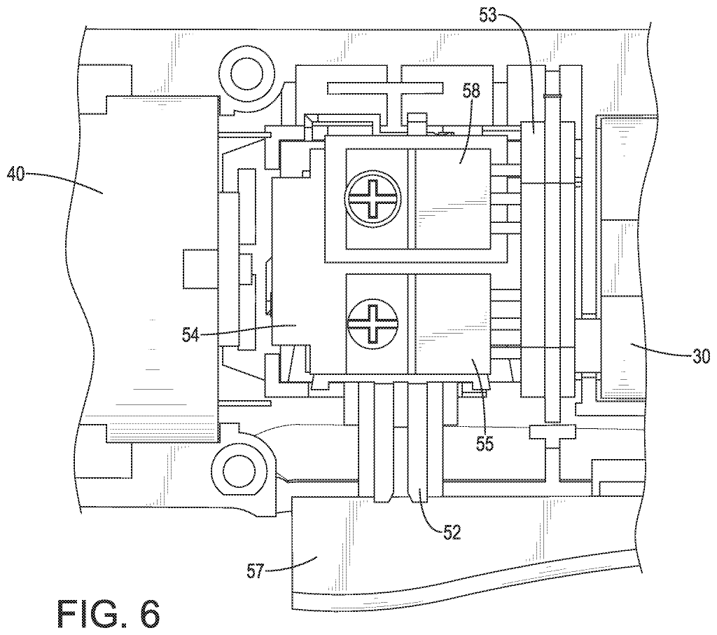

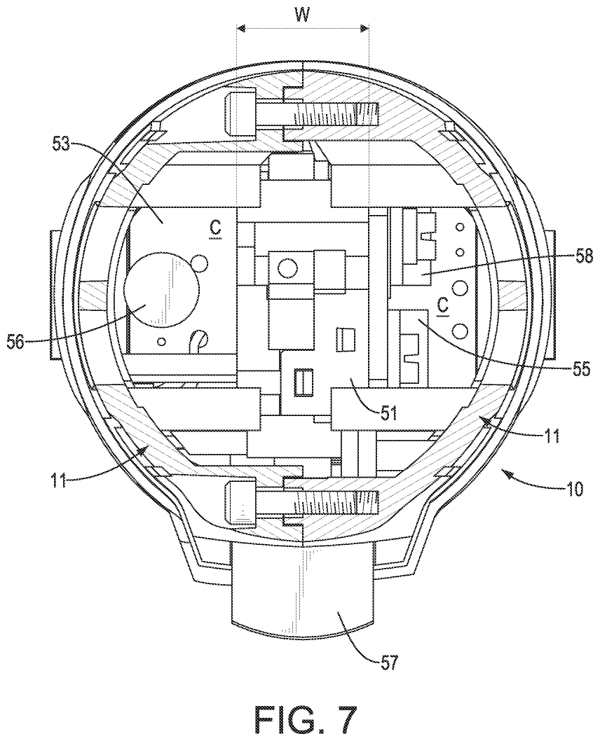

With reference to FIGS. 4, 6, and 7, the switch 51 has a length L and a width W. The length L is defined along a lengthwise direction of the housing 10. An edge of the switch 51 extending along the length L of the switch 51 is defined as a lengthwise edge of the switch 51. The width W is defined along a radial direction of the housing 10. An edge of the switch 51 extending along the width W of the switch 51 is defined as a widthwise edge of the switch 51. The length L of the switch 51 is larger than the width W of the switch 51. The lengthwise edge of the switch 51 extends along an axial direction of the housing 10. The widthwise edge of the switch 51 extends along a radial direction of the housing 10. Therefore, two convection passages C are formed between the switch 51 and the housing 10. The two convection passages C respectively communicate with the two convection passages C.

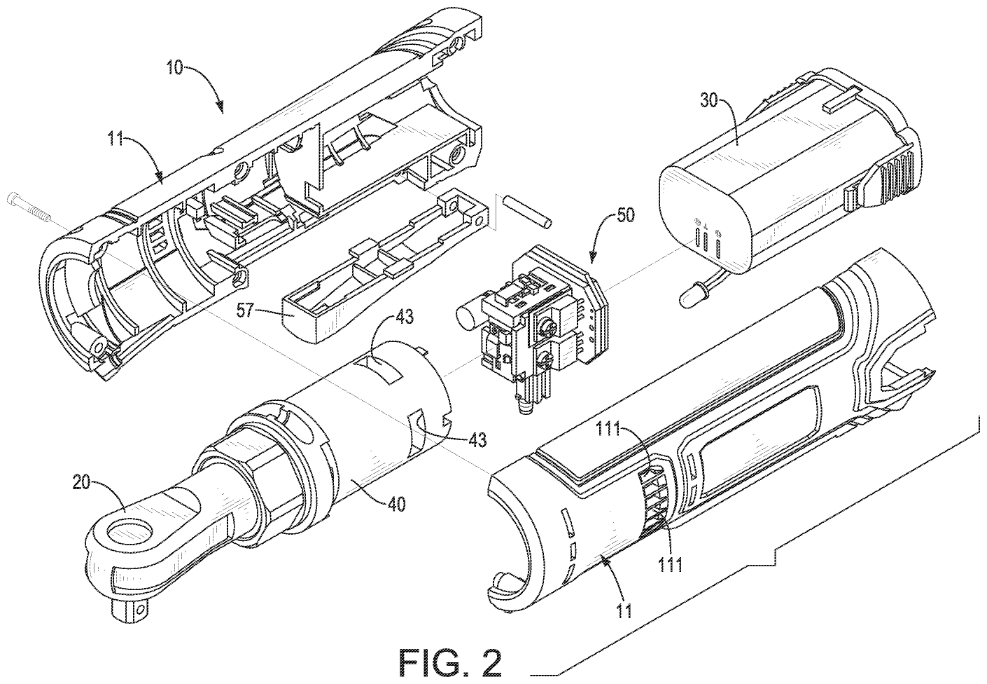

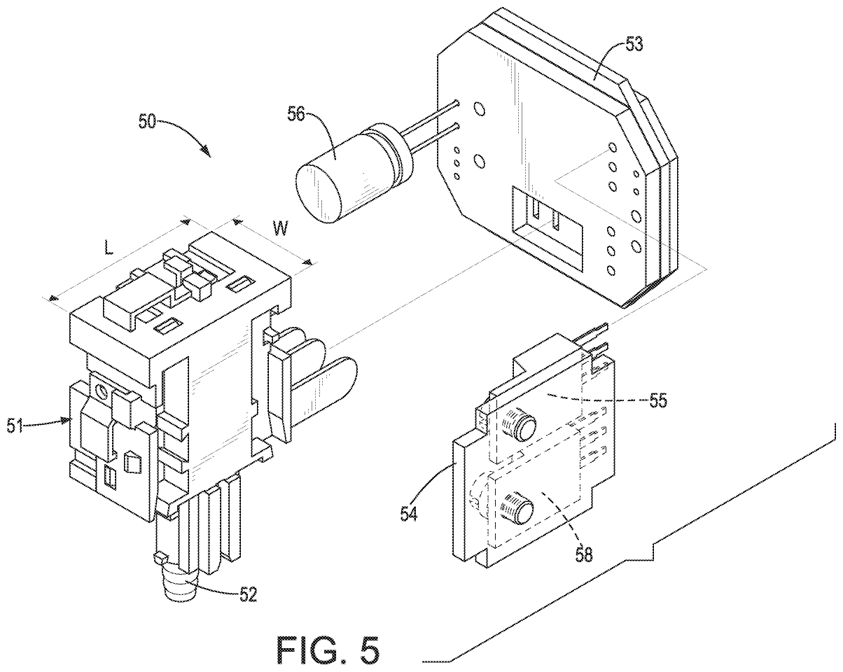

With reference to FIGS. 2 to 4, the button 52 is disposed at the switch 51. The controlling circuit board 53 is connected to the switch 51 and is disposed between the switch 51 and the battery 30. The field-effect transistor 58 is a metal-oxide-semiconductor field-effect transistor (MOSFET). The freewheeling diode 55 and the field-effect transistor 58 are juxtaposed, are inserted into the controlling circuit board 53, and are disposed between the switch 51 and one of the shells 11. The freewheeling diode 55 and the field-effect transistor 58 are electrically connected to the controlling circuit board 53. The heat-dissipation board 54 is connected to the freewheeling diode 55 and the field-effect transistor 58 and is disposed in one of the two convection passages C. The heat-dissipation board 54 may be disposed between the switch 51 and the freewheeling diode 55 and the field-effect transistor 58 that are juxtaposed with each other. In addition, with reference to FIG. 5, the heat-dissipation board 54 may be disposed between one of the shells 11 and the freewheeling diode 55 and the field-effect transistor 58 that are juxtaposed with each other. The heat-dissipation board 54 may be made of a large-area metal board with a small specific heat. Practically, the freewheeling diode 55 provides a current protection function to prevent the switch 51 from generating a surge current.

With reference to FIGS. 2 to 4, the freewheeling diode 55 and the field-effect transistor 58 may respectively have three pins. The three pins of the freewheeling diode 55 and the three pins of the field-effect transistor 58 are electrically connected to the controlling circuit board 53. The capacitor 56 and the freewheeling diode 55 and the field-effect transistor 58 that are juxtaposed with each other are respectively disposed in the two convection passages C respectively disposed at two sides of the switch 51. The pressing operator 57 is movably assembled to the housing 10 and corresponds to the button 52 in position. When the pressing operator 57 is pressed, it abuts the button 52 to control the operation of the present invention. When the power tool of the present invention operates, air inside the power tool is expelled by the centrifugal fan via the passages C, the at least one ventilation hole 41, the at least one heat-dissipation hole 43, and from the convection holes 111. Therefore, heat generated by the operating control assembly 50 can be exhausted efficiently.

By structures mentioned above, advantages of the present invention are as follows:

1. In the present invention, the switch 51 of the control assembly 50 has the length L larger than width W of the switch 51. The two convection passages C are formed between the switch 51 and the housing 10 to facilitate ventilation inside the present invention and promote heat-dissipation efficiency of the present invention.

2. In the present invention, the controlling circuit boards of the conventional power tool are integrated as the single controlling circuit board 53 arranged between the switch 51 and the battery 30 to avoid a circumstance that the controlling circuit board 53 blocks the ventilation hole 41 disposed at a rear end of the motor 40. Therefore, the heat-dissipation efficiency of the present invention is further promoted. As the only controlling circuit board 53 is arranged between the switch 51 and the battery 30, the present invention is free from preserving spaces for running cables. The control assembly 50 is shortened accordingly, and an overall length of the present invention is further shortened as well.

3. The controlling circuit board 53 is electrically connected to the freewheeling diode 55 to provide the current protection function and prevents the switch 51 from generating a surge current.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A power tool comprising:
a housing having
a receiving space formed in the housing; and
a first end and a second end disposed oppositely on the housing;
an output head disposed at the first end of the housing;
a battery disposed within the receiving space and adjacent to the second end of the housing;
a motor disposed within the receiving space, disposed adjacent to the first end of the housing, and connected to the output head; and
a control assembly disposed within the receiving space, disposed between the battery and the motor, electrically connected to the battery and the motor, and having
a switch having
a length defined along a lengthwise direction of the housing; and
a width defined along a radial direction of the housing and being smaller than the length of the switch to form two convection passages between the switch and the housing; and
a controlling circuit board disposed between the switch and the battery.

2. The power tool as claimed in claim 1, wherein the motor has at least one ventilation hole facing to the second end of the housing.

3. The power tool as claimed in claim 2, wherein the housing is formed by attaching two shells, each one of the two shells of the housing has multiple convection holes radially formed through the shell, and the convection holes of the shell communicate with the two convection passages.

4. The power tool as claimed in claim 3, wherein the control assembly has a field-effect transistor electrically connected to the controlling circuit board and disposed between the switch and one of the two shells.

5. The power tool as claimed in claim 4, wherein the control assembly has a freewheeling diode electrically connected to the controlling circuit board and disposed between the switch and one of the two shells.

6. The power tool as claimed in claim 5, wherein the control assembly has a heat-dissipation board connected to the field-effect transistor and disposed within one of the two convection passages.

7. The power tool as claimed in claim 6, wherein the freewheeling diode and the field-effect transistor are juxtaposed, and the heat-dissipation board is connected to the freewheeling diode.

8. The power tool as claimed in claim 7, wherein the heat-dissipation board is disposed between the switch and the freewheeling diode and the field-effect transistor that are juxtaposed with each other.

9. The power tool as claimed in claim 7, wherein the heat-dissipation board is disposed between one of the two shells and the field-effect transistor and the freewheeling diode that are juxtaposed with each other.

10. The power tool as claimed in claim 4, wherein
the control assembly has a capacitor electrically connected to the controlling circuit board; and
the capacitor and the field-effect transistor are respectively disposed at two sides of the switch.

11. The power tool as claimed in claim 5, wherein
the control assembly has a capacitor electrically connected to the controlling circuit board; and
the capacitor and the field-effect transistor are respectively disposed at two sides of the switch.

12. The power tool as claimed in claim 6, wherein
the control assembly has a capacitor electrically connected to the controlling circuit board; and
the capacitor and the field-effect transistor are respectively disposed at two sides of the switch.

13. The power tool as claimed in claim 7, wherein
the control assembly has a capacitor electrically connected to the controlling circuit board; and
the capacitor and the field-effect transistor are respectively disposed at two sides of the switch.

14. The power tool as claimed in claim 8, wherein
the control assembly has a capacitor electrically connected to the controlling circuit board; and
the capacitor and the field-effect transistor are respectively disposed at two sides of the switch.
